(19) United States
(12) Patent Application Publication
(10) Pub. No.: US 2025/0203896 A1
(43) Pub. Date: Jun. 19, 2025

(54) SEMICONDUCTOR DEVICE

(71) Applicant: Renesas Electronics Corporation, Tokyo (JP)

(72) Inventors: Kazuhiko IWAKIRI, Tokyo (JP); Ryota KURODA, Tokyo (JP)

(21) Appl. No.: 18/928,310

(22) Filed: Oct. 28, 2024

(30) Foreign Application Priority Data
Dec. 14, 2023 (JP) 2023-210820

(51) Int. Cl. H01L 29/739; H01L 27/088; H01L 29/08; H01L 29/423

(52) U.S. Cl. CPC H10D 12/481; H10D 62/151; H10D 64/513; H10D 84/83

(57) ABSTRACT

An IGBT includes a first trench gate electrode extending in a first width direction, and a second trench gate electrode facing the first trench gate electrode. A first position range in the first width direction of a first channel region formed by the first trench gate electrode and a second position range in the first width direction of a second channel region formed by the second trench gate electrode differ from each other.

### CROSS-REFERENCE TO RELATED APPLICATIONS

The disclosure of Japanese Patent Application No. 2023-210820 filed on Dec. 14, 2023 including the specification, drawings and abstract is incorporated herein by reference in its entirety.

### BACKGROUND

The present invention relates to a semiconductor device, and particularly relates to a semiconductor device such as an insulated gate bipolar transistor (IGBT) having a plurality of trench gate electrodes.

There are disclosed techniques listed below.
[Patent Document 1] Japanese Unexamined Patent Application Publication No. 2013-140885

Patent Document 1 describes a technique related to an injection enhancement (IE) type trench gate IGBT utilizing an IE effect. The IE type trench gate IGBT includes an active cell region and a hole collector cell region.

### SUMMARY

The IE type trench gate IGBT has a problem in that current tends to concentrate at a lower portion of the active cell region.

Other problems and novel features will become apparent from the description of the present specification and the accompanying drawings.

A semiconductor device according to an embodiment includes a first trench gate electrode extending in a first width direction, and a second trench gate electrode facing the first trench gate electrode. A first position range in the first width direction of a first channel region formed by the first trench gate electrode and a second position range in the first width direction of a second channel region formed by the second trench gate electrode differ from each other.

According to the embodiment, it is possible to provide a semiconductor device configured to suppress current from concentrating in a lower portion of an active cell region.

### BRIEF DESCRIPTION OF THE DRAWINGS

FIG. 1 is a drawing for describing an overview of an IGBT according to a comparative example.

FIG. 2 is schematic cross-sectional view of an active cell region of the IGBT according to the comparative example.

FIG. 3 is a schematic top view of the active cell region of the IGBT according to the comparative example.

FIG. 4 is a schematic top view of an IGBT according to a first embodiment.

FIG. 5 is a schematic top view of the IGBT according to the first embodiment.

FIG. 6 is a schematic top view of the IGBT according to the first embodiment.

FIG. 7 is a schematic top view of the IGBT according to the first embodiment.

FIG. 8 is a schematic top view of the IGBT according to the first embodiment.

FIG. 9 is a drawing describing an equivalent circuit of the IGBT according to the first embodiment.

FIG. 10 is a schematic top view of the IGBT according to the first embodiment.

FIG. 11 is a schematic top view of the IGBT according to the first embodiment.

FIG. 12 is a drawing describing results of thermal analysis performed on the IGBT according to the first embodiment.

FIG. 13 is a drawing describing results of thermal analysis performed on the IGBT according to the first embodiment.

### DETAILED DESCRIPTION

The following descriptions and drawings have been abbreviated and simplified as appropriate for clarity. In each of the drawings, identical elements are denoted by an identical reference sign, and redundant: descriptions are omitted as appropriate.

### [Considerations Leading to the Embodiment]

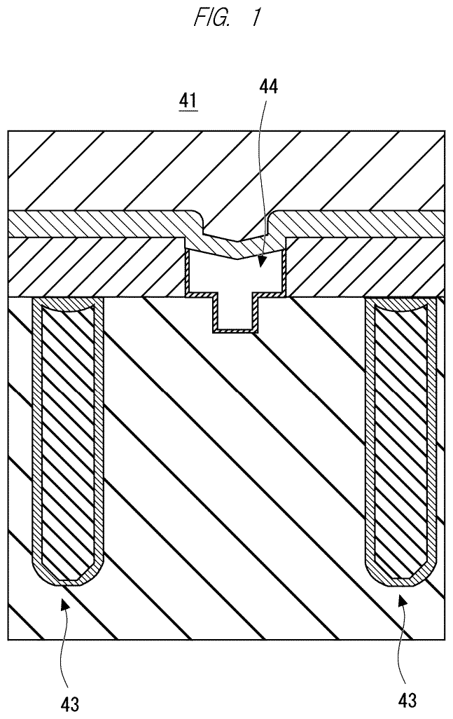

First, an IGBT 10 according to a comparative example will be described. An overview of the IGBT 10 according to the comparative example will be described with reference to FIG. 1. The IGBT 10 includes an active cell region 41. A trench 43 is formed in the active cell region 41. An electrode embedded in the trench 43 formed in the active cell region 41 is connected to a gate. The active cell region 41 is basically configured in the same manner as an IE type trench-gate IGBT according to a conventional technique. However, this differs in that tungsten is injected into a contact injection region 44 and that it has a shrink structure.

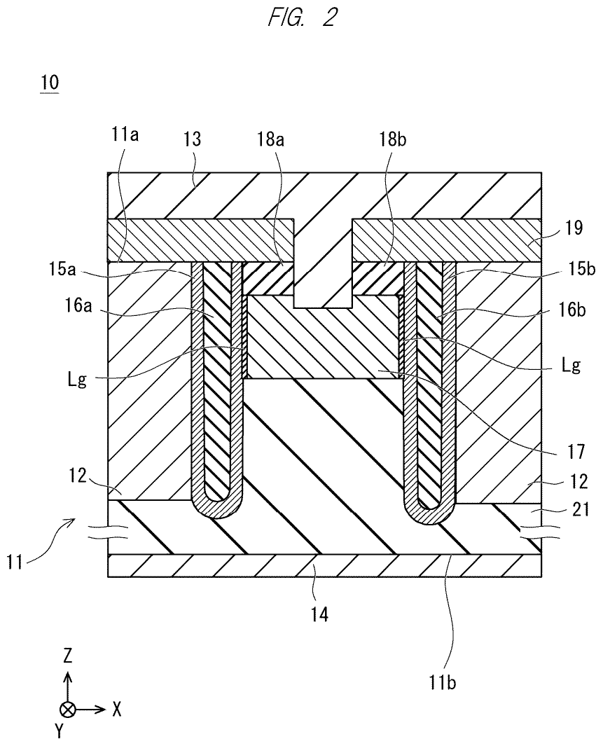

FIG. 2 is a schematic cross-sectional view of the active cell region of the IGBT 10. The IGBT 10 includes an n type semiconductor substrate 11. The semiconductor substrate 11 has a main surface 11a and a main surface 11b. The main surface 11b is a surface on the opposite side of the main surface 11a. The semiconductor substrate 11 includes, for example, silicon as a material.

Here, for convenience of explanation, an XYZ Cartesian coordinate system is introduced. A direction orthogonal to the main surface 11a and the main surface 11b is defined as a Z axis direction, and a direction from the main surface 11b toward the main surface 11a is defined as a +Z axis direction. Two orthogonal directions in a plane parallel to the main surface 11a and the main surface 11b are respectively defined as an X axis direction and a Y axis direction. The +Z axis direction is also referred to as upward and a −Z axis direction is also referred to as downward. Note that the X axis, Y axis, and Z axis directions, and upward and downward are used for convenience in describing the IGBT 10 and do not indicate the directions in which the IGBT 10 is used.

The semiconductor substrate 11 includes an n type semiconductor region 21. A p type well region 12 is formed around the active cell region. In addition, an emitter electrode 13 is formed on the main surface 11a side of the semiconductor substrate 11, and a collector electrode 14 is formed on the main surface 11b side of the semiconductor substrate 11.

Two trenches are formed in the semiconductor region on the main surface 11a side of the semiconductor substrate 11. One of the trenches has a trench gate electrode 16a embedded via a gate insulating film 15a. The other trench has a trench gate electrode 16b embedded via a gate insulating film 15b. If the gate insulating film 15a and 15b need not be distinguished from each other, they may simply be referred to as a gate insulating film 15. If the trench gate electrodes 16a and 16b need not be distinguished from each other, they may simply be referred to as a trench gate electrode 16. The gate insulating film 15a insulates the trench gate electrode 16a from a channel region (also referred to as a first channel region) formed by the trench gate electrode 16a. Likewise, the gate insulating film 15b insulates the trench gate electrode 16b from a channel region (also referred to as a second channel region) formed by the trench gate electrode 16b.

A p type semiconductor region 17 is formed between the trench gate electrode 16a and the trench gate electrode 16b, and n type source regions 18a and 18b are formed on its surface. Reference sign “Lg” represents a channel length of each of the channels formed by the trench gate electrodes 16a and 16b. The source region 18a is in contact with the gate insulating film 15a, and the source region 18b is in contact with the gate insulating film 15b. If the source regions 18a and 18b need not be distinguished from each other, they may simply be referred to as a source region 18. The source region 18a injects carriers (e.g., electrons) into the first channel region. The source region 18b injects carriers into the second channel region.

An oxide film 19 is deposited on a s surface of the semiconductor substrate 11, and openings are formed in the oxide film 19. The source regions 18a and 18b are electrically connected to the emitter electrode 13 via the openings in the oxide film 19.

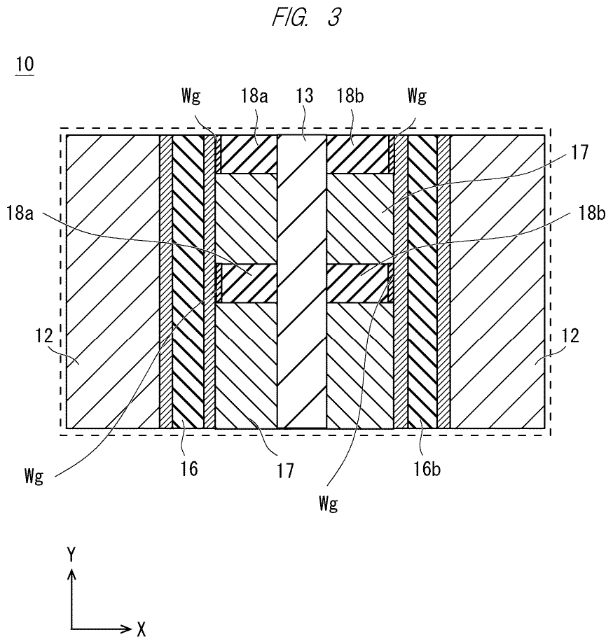

FIG. 3 is a schematic top view of a cell region of the IGBT 10. The oxide film 19 and a portion of the emitter electrode 13 are omitted from the figure for clarity.

The trench gate electrodes 16a and 16b extend in the Y direction. Regions in which the source region 18 is formed and regions in which the source region 18 is not formed are alternatively provided along the Y direction.

Reference sign “Wg” represents a channel width of each of the channels formed by the trench gate electrode 16. The channel width represents a length of the channel region in the Y direction. A position range (also referred to as a first position range) in the Y direction of the channel region (first channel region) formed by the trench gate electrode 16a and a position range (also referred to as a second position range) in the Y direction of the channel region (second channel region) formed by the second trench gate electrode 16b overlap each other.

In the IGBT 10, the first position range and the second position range described above overlap each other, causing current to easily concentrate in the lower portion of the active cell region and resulting in heat generation.

### First Embodiment

In an IGBT 100 according to the first embodiment, the first position range and the second position range described above differ from each other. This prevents current from concentrating in the lower portion of the active cell region.

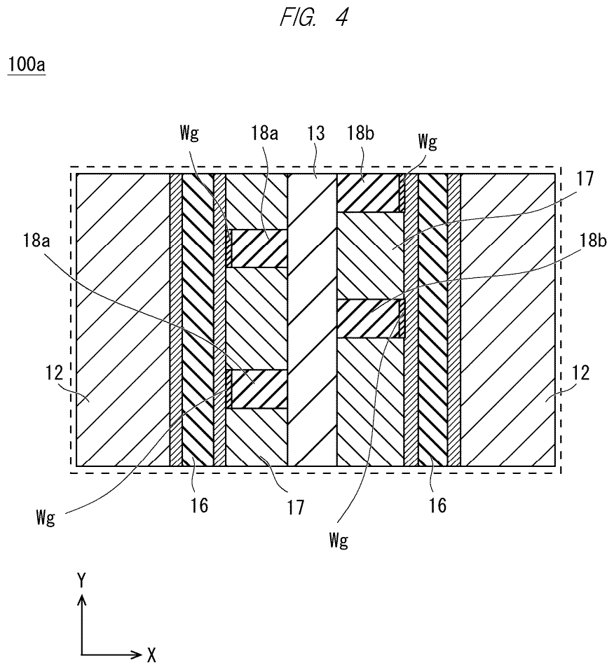

FIG. 4 is a schematic top view of an IGBT 100a, which is a first specific example of the IGBT 100. A position range in the Y direction of the source region 18a and a position range in the Y direction of the source region 18b are configured so as to not overlap each other. Therefore, the first position range and the second position range described above do not overlap each other. In the IGBT 100a, the first position range and the second position range do not overlap each other, making it particularly effective in suppressing current concentration. Note that a length of the source region 18a in the Y direction and a length of the source region 18b in the Y direction per unit area (area surrounded by dotted lines) have not been changed from the IGBT 10, making it possible to obtain sufficient current output.

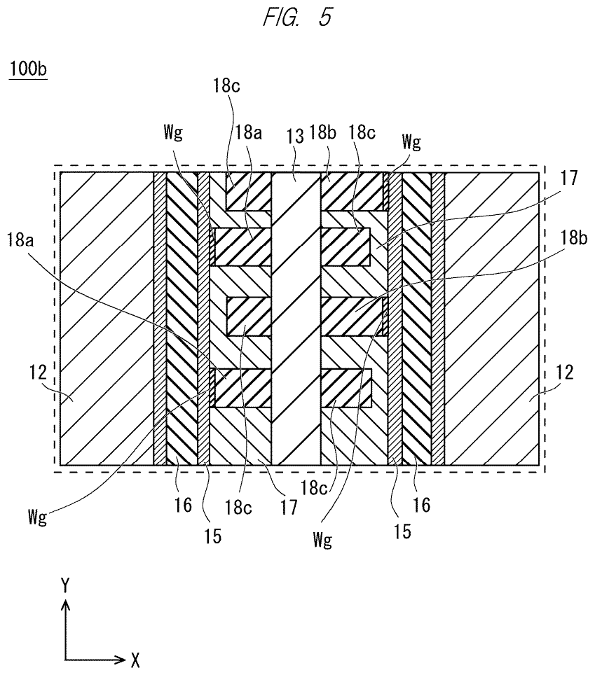

FIG. 5 is a schematic top view of an IGBT 100b, which is a second specific example of the IGBT 100. The IGBT 100b of FIG. 5 differs from the IGBT 100a of FIG. 4 in that an n type semiconductor region 18c is added. Patterns including the source region 18a, the source region 18b, and the semiconductor region 18c are relatively less detailed, providing an advantage of making lithography less difficult. Note that the semiconductor region 18c is not in contact with the gate insulating film 15, and thus, no channel region is formed around the semiconductor region 18c. The first position range and the second position range do not overlap each other, making it possible for the IGBT 100b to have a similar effect as the IGBT 100a.

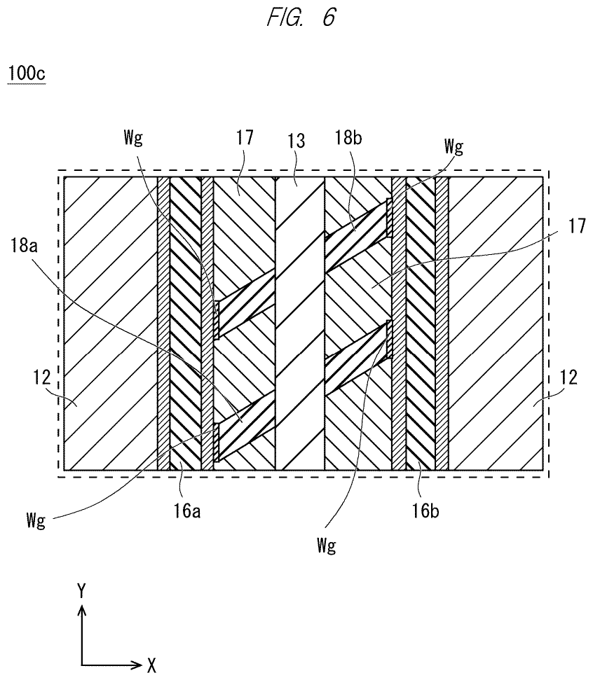

FIG. 6 is a schematic top view of an IGBT 100c, which is a third specific example of the IGBT 100. The source regions 18a and 18b are provided along a straight line extending diagonally with respect to an X direction. The first position range and the second position range described above do not overlap each other, making it possible for the IGBT 100c to have a similar effect as the IGBT 100a. In addition, there is an advantage in that patterns including the source regions 18a and 18b are relatively less detailed.

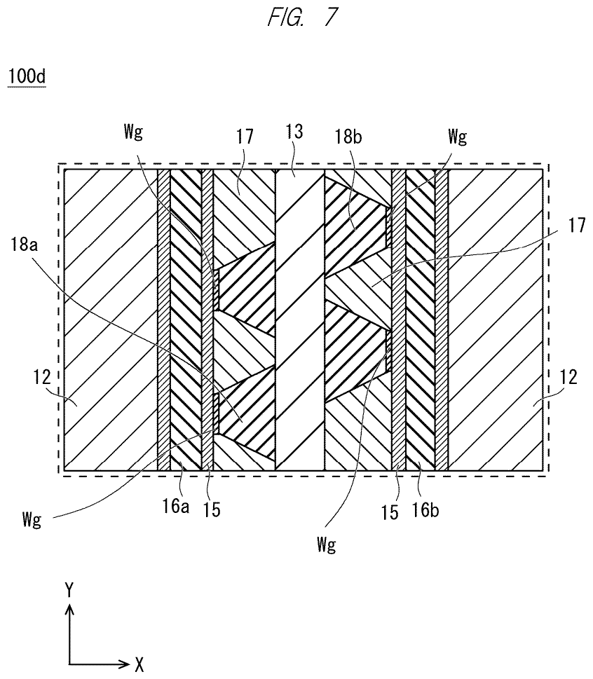

FIG. 7 is a schematic top view of an IGBT 100d, which is a fourth specific example of the IGBT 100. The source region 18 is formed in a trapezoidal shape, with a shorter bottom portion of the trapezoid (also known as a top base) in contact with the gate insulating film 15. The source regions 18a and 18b are arranged offset from each other in the Y direction and have a similar effect as the IGBT 100a. In addition, there is an advantage in that patterns including the source regions 18a and 18b are relatively less detailed.

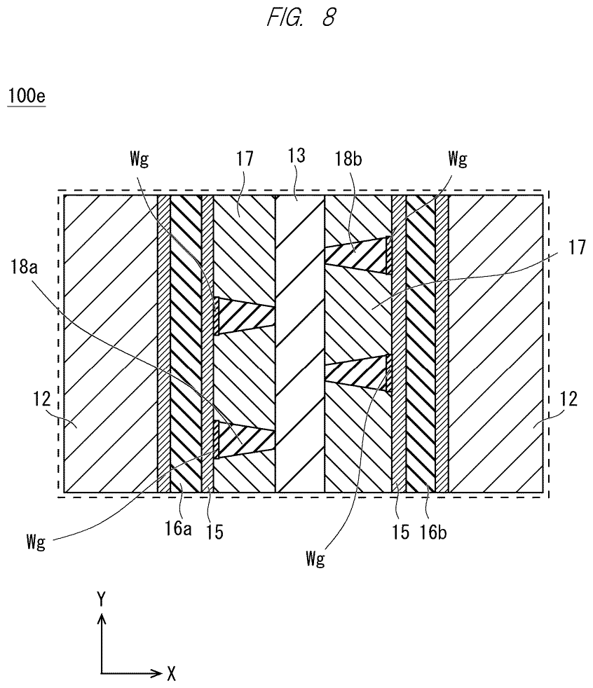

FIG. 8 is a schematic top view of an IGBT 100e, which is a fifth specific example of the IGBT 100. The source region 18 is formed in a trapezoidal shape, with a longer bottom portion of the trapezoid (also known as a bottom base) in contact with the gate insulating film 15. The source regions 18a and 18b are arranged offset from each other in the Y direction and have a similar effect as the IGBT 100a. In addition, there is an advantage in that the IGBT 100e is less prone to a parasitic bipolar action that can lead to thermal breakdown.

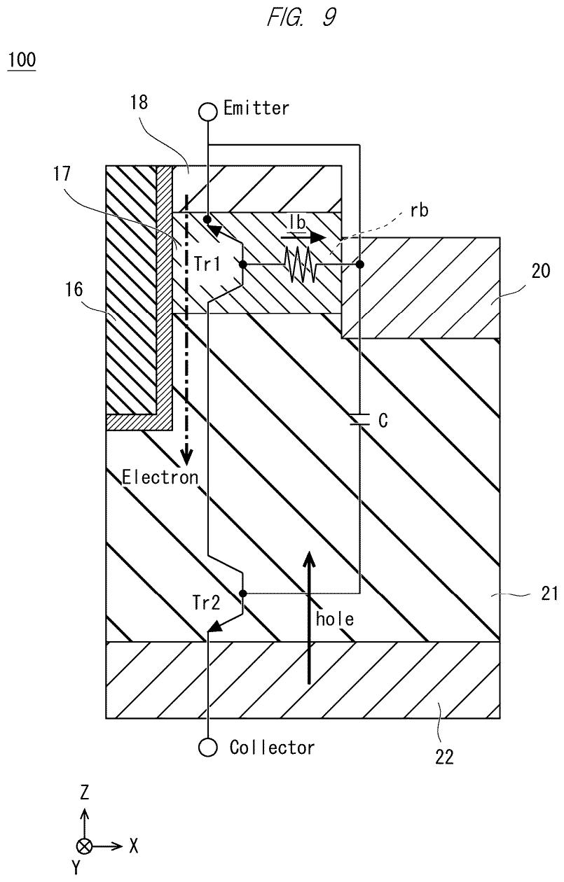

FIG. 9 is a drawing for describing an equivalent circuit of the IGBT 100. The IGBT 100 includes bipolar transistors Tr1 and Tr2 connected in series with each other. A base of the transistor Tr1 is connected to a p+ type semiconductor region 20 (contact) via a base resistor rb. A p+ type semiconductor region 22 (contact) is formed below the n type semiconductor region 21. A base of the bipolar transistor Tr2 is connected to the p+ type semiconductor region 20 via a capacitor C.

A voltage drop between an emitter and the base of the bipolar transistor Tr1 is calculated as a product of a hole current Ib flowing in the resistor rb and a value of the resistor rb. If the voltage drop between the emitter and the base is large, the parasitic bipolar transistor Tr1 will be turned on, resulting in a large current that cannot be controlled by a gate voltage and causing thermal breakdown of the IGBT 100. In the IGBT 100e, a contact area between the source region 18 and the emitter electrode 13 (or a contact thereof) is small, making it easier for the hole current to flow and the resistor rb to be lowered, and making it more difficult for the bipolar transistor Tr1 to be turned on, thereby reducing the possibility of thermal breakdown.

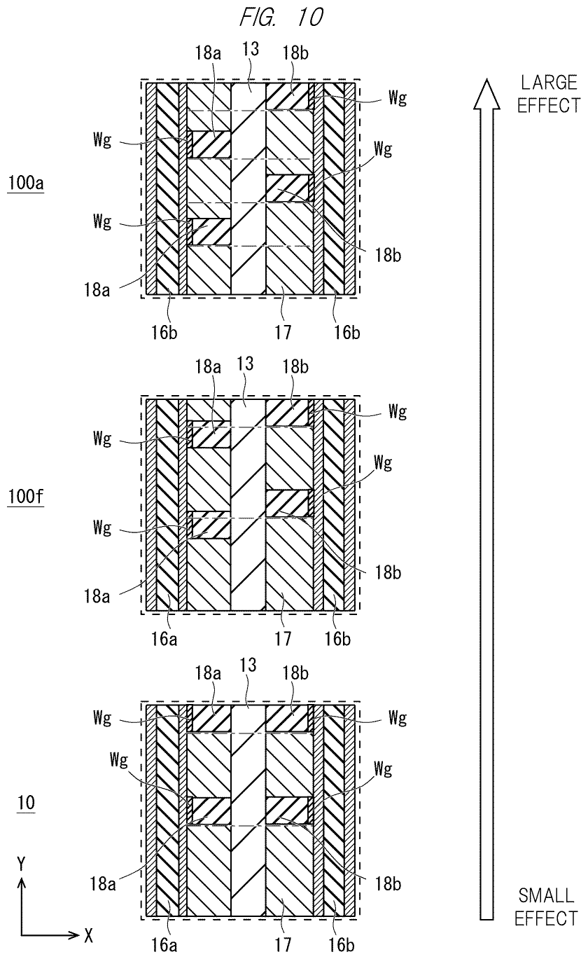

Hereinafter, an IGBT 100f, which is a sixth specific example of the IGBT 100, will be described with reference to FIG. 10. The bottom drawing in FIG. 10 shows a schematic top view of the IGBT 10 according to the comparative example, the middle drawing shows a schematic top view of the IGBT 100f, and the top drawing shows a schematic top view of the above-described IGBT 100a.

In the IGBT 100f shown in the middle drawing, the source region 18a and the source region 18b are arranged offset from each other in the Y direction. Therefore, the first position range and the second position range described above differ from each other. In the IGBT 100f, the first position range and the second position range partially overlap unlike the IGBT 100a and have a certain effect in preventing current concentration. However, the effect of the IGBT 100f is smaller than that of the IGBT 100a.

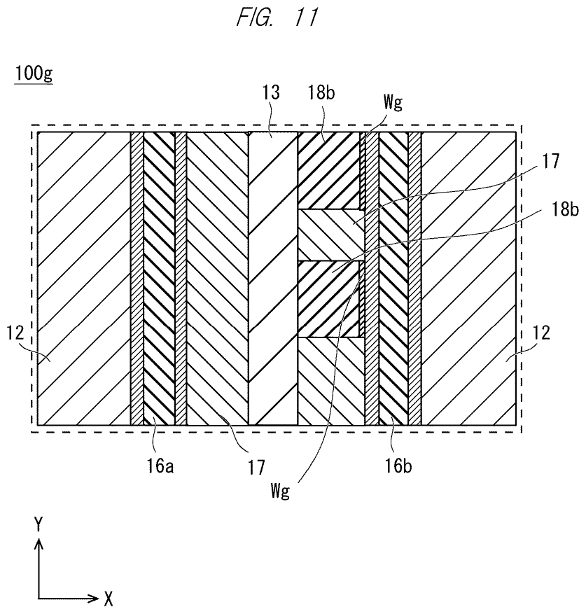

FIG. 11 is a schematic top view of an IGBT 100g, which is a seventh example of the IGBT 100. The IGBT 100g has the source region 18b and does not have the source region 18a. The length of the source region 18b of the IGBT 100g in the Y direction is twice the length of the source region 18b of the IGBT 10 in the Y direction.

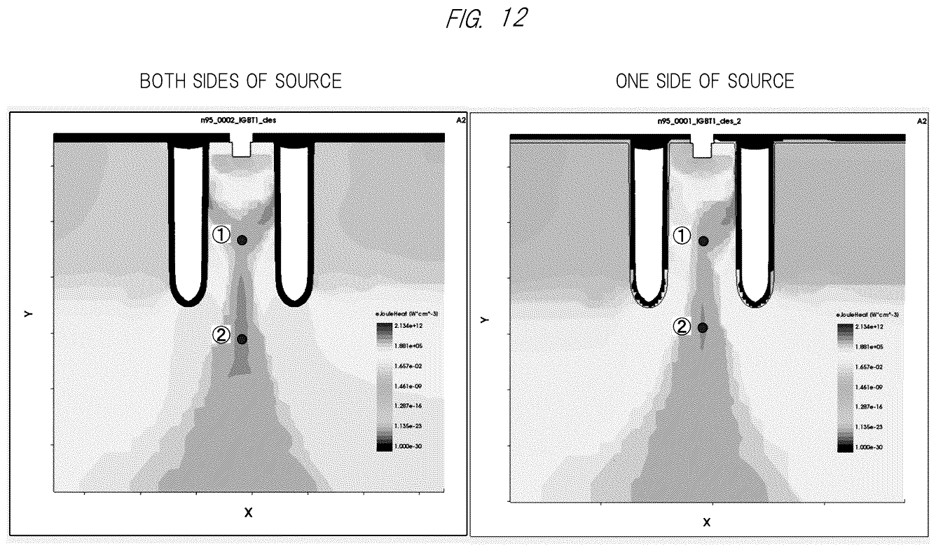

FIG. 12 shows results of thermal analysis performed on the IGBT 10 according to the comparative example and results of thermal analysis performed on the IGBT 100g in a heatmap format. The drawing on the left shows results of the thermal analysis performed on the IGBT 10, and the drawing on the right shows results of the thermal analysis performed on the IGBT 100g. “1” indicates a point where electron currents join in the IGBT 10, and “2” indicates a point with the highest temperature.

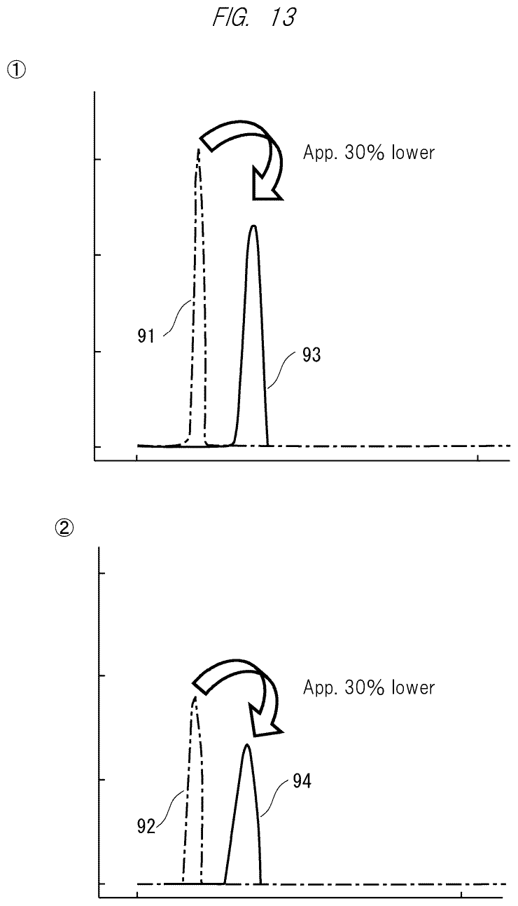

FIG. 13 shows monitored results of Joule heat over time in “1” and “2”. The top drawing shows the monitored results for “1”, and the bottom drawing shows the monitored results for “2”. A curve 91 in the top drawing and a curve 92 in the bottom drawing represent the monitored results for IGBT 10. A curve 93 in the top drawing and a curve 94 in the bottom drawing represent the monitored results for the IGBT 100g. For both “1” and “2”, the Joule heat generated in the IGBT 100g is reduced by approximately 30% from the Joule heat generated in the IGBT 10. Therefore, the IGBT 100g can reduce the generation of Joule heat. Likewise, it is considered that the IGBTs 100a to 100f can also reduce the generation of Joule heat.

The IGBT 100 according to the first embodiment can prevent current from concentrating in the lower portion of the active cell region and suppress the generation of Joule heat.

In the foregoing, the invention made by the present inventor has been described in detail based on the embodiments. However, it goes without saying that the present invention is not limited to the above-described embodiments, and can be changed in various ways without departing from the gist of the invention.

For example, the IGBT according to the foregoing embodiments may have a configuration in which conductivity types (p type or n type) of a semiconductor substrate, semiconductor layer, diffusion layer (diffusion region), or the like are inverted. Therefore, when one of the n type and the p type conductivity type is a first conductivity type and the other conductivity type is a second conductivity type, the first conductivity type can be the p type and the second conductivity type can be the n type, or conversely, the first conductivity type can be the n type and the second conductivity type can be the p type.

In the above-described embodiments, a case where the semiconductor device is an IGBT has been described as an example. However, the semiconductor device is not limited to such a configuration. The above-described embodiments can also be applied to a semiconductor device other than an IGBT, such as a power MOSFET (Metal Oxide Semiconductor Field Effect Transistor).

What is claimed is:

1. A semiconductor device comprising:
a first trench gate electrode extending in a first width direction; and
a second trench gate electrode facing the first trench gate electrode,
wherein a first position range in the first width direction of a first channel region formed by the first trench gate electrode and a second position range in the first width direction of a second channel region formed by the second trench gate electrode differ from each other.

2. The semiconductor device according to claim 1,
wherein the first position range and the second position range do not overlap each other.

3. The semiconductor device according to claim 2, further comprising:
a first gate insulating film configured to insulate the first trench gate electrode from the first channel region;
a second gate insulating film configured to insulate the second trench gate electrode from the second channel region;
a first source region configured to inject carriers into the first channel region; and
a second source region configured to inject carriers into the second channel region,
wherein the first source region and the second source region are provided along a straight line extending diagonally with respect to a second width direction orthogonal to the first width direction.

4. The semiconductor device according to claim 2, further comprising:
a first gate insulating film configured to insulate the first trench gate electrode from the first channel region;
a second gate insulating film configured to insulate the second trench gate electrode from the second channel region;
a first source region configured to inject carriers into the first channel region; and
a second source region configured to inject carriers into the second channel region,
wherein the first source region and the second source region are formed in a trapezoidal shape when viewed from above, and a shorter bottom portion of the trapezoidal shape is in contact with the first gate insulating film or the second gate insulating film.

5. The semiconductor device according to claim 2, further comprising:
a first gate insulating film configured to insulate the first trench gate electrode from the first channel region;
a second gate insulating film configured to insulate the second trench gate electrode from the second channel region;
a first source region configured to inject carriers into the first channel region; and
a second source region configured to inject carriers into the second channel region,
wherein the first source region and the second source region are formed in a trapezoidal shape when viewed from above, and a longer bottom portion of the trapezoidal shape is in contact with the first gate insulating film or the second gate insulating film.
